(19) United States
(12) Patent Application Publication
(10) Pub. No.: US 2026/0178093 A1
(43) Pub. Date: Jun. 25, 2026

(54) VOLTAGE ISOLATION SYSTEM FOR A MICROCHIP

(71) Applicant: Infineon Technologies AG, Neubiberg (DE)

(72) Inventors: Peter Bogner, Wernberg (AT); Robert Priewasser, Stammham (DE)

(21) Appl. No.: 19/374,248

(22) Filed: Oct. 30, 2025

(30) Foreign Application Priority Data
Oct. 31, 2024 (DE) 102024210530.9

(51) Int. Cl. G06F 1/26

(52) U.S. Cl. CPC G06F 1/263

(57) ABSTRACT

A mechanism for controlling power flow from a voltage line to an electronic circuit of a microchip. A reset control system initially controls a voltage isolation circuit to prevent this power flow upon startup of the microchip and allows it only when one or more predetermined criteria are met. The voltage monitoring system generates a digital representation of the voltage at a supply line, which the reset control system monitors. The reset control system monitors the digital representation of this voltage to determine when the one or more predetermined criteria are met.

### REFERENCE TO RELATED APPLICATION

This application claims priority to German Application number 102024210530.9, filed on Oct. 31, 2024, the contents of which are hereby incorporated by reference in their entirety.

### TECHNICAL FIELD

The present disclosure relates to microchips, and in particular, to voltage isolation systems for microchips.

### BACKGROUND

Microchips are becoming increasingly widespread in modern electronic devices, playing crucial roles in various applications ranging from consumer electronics to automotive systems and industrial equipment. As microchips become more complex and integrate multiple functions, managing power distribution and ensuring proper voltage levels across different components becomes increasingly challenging.

In safety-critical applications, such as those found in the automotive industry, there is a strong desire for microchips to perform at least two key tasks related to power management. First, a microchip should monitor all supply voltages (of different power domains) to ensure proper operation of the various components. Second, a microchip may need to ensure that no unexpected current paths are enabled during power-up sequences or when supply voltage conditions are invalid. This second feature is often referred to as isolation of power domains.

For the sake of completeness, it is noted that a power domain is a section or region of a microchip that operates at a specific voltage level and is provided with a supply for providing said voltage level. Power domains allow different parts of the microchip to function at different voltage levels, which can help optimize power consumption and performance and facilitate integration with other components requiring different power levels (e.g., operating according to different standards). This subdivision of power distribution thereby enables more efficient and granular power management strategies, especially in complex microchips such as systems-on-chip (SoCs), where various components may have different power requirements or operational states.

There is an ongoing desire to configure a microchip to perform these two tasks reliably and efficiently.

### SUMMARY

There is herein proposed a voltage isolation system for controlling, in a microchip, a power flow from a voltage line to an electronic circuit.

The voltage isolation circuit comprises a voltage isolation circuit configured to control a power flow between the voltage line and the electronic circuit responsive to a control signal; a voltage monitoring system configured to generate a digital representation of a voltage at a supply line for the electronic circuit; and a reset control system configured to provide the control signal to the voltage isolation circuit and receive and monitor the digital representation of the voltage at the supply line from the voltage monitoring system.

The reset control system is further configured to, responsive to a startup of the microchip, initially control, using the control signal, the voltage isolation circuit to prevent power flow from the voltage line to the electronic circuit. Responsive to each of one or more first predetermined criteria being met after the startup of the microchip, the reset control system permits the voltage isolation circuit to allow power flow from the voltage line to the electronic circuit, wherein the one or more first predetermined criteria includes a criterion that the digital representation of the voltage at the supply line meets each of one or more second predetermined criteria after the startup of the microchip.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a portion of an exemplary microchip.

FIG. 2 illustrates an example voltage isolation system, in accordance with various aspects discussed.

FIG. 3 illustrates a microchip that includes an example voltage isolation system, in accordance with various aspects discussed.

FIG. 4 illustrates a portion of an example microchip, in accordance with various aspects discussed.

### DETAILED DESCRIPTION

The examples described herein provide a mechanism for controlling power flow from a voltage line to an electronic circuit of a microchip. A reset control system initially controls a voltage isolation circuit to prevent this power flow upon startup of the microchip and allows power flow only when one or more predetermined criteria are met. The voltage monitoring system generates a digital representation of the voltage at a supply line, which the reset control system monitors. The reset control system monitors the digital representation of this voltage to determine when the one or more predetermined criteria are met.

More particularly, the disclosed approach effectively proposes to integrate or combine voltage monitoring and voltage/power isolation control into a single system. This integration leads to more compact layouts and improved power efficiency.

In the context of the present disclosure, the term “microchip” does not necessarily mean that there is only a single semiconductor die in a package. In some cases, a microchip may comprise, in addition to one or more cores, register memory and some additional functionality, one or more additional chiplets that are incorporated into a single package, for example providing memory or input output functionality. Thus, a microchip may comprise one or more semiconductor dies and/or chiplets incorporated into a single package.

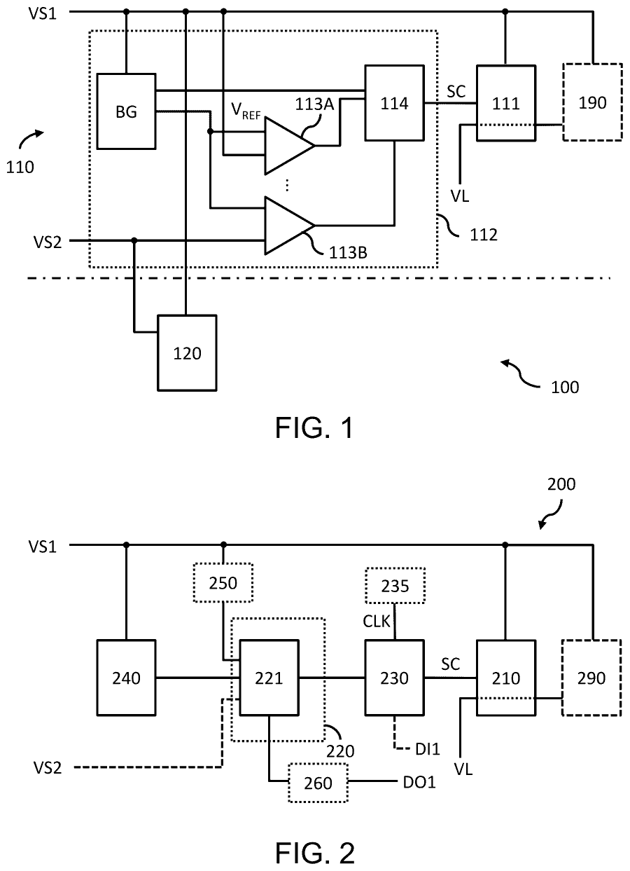

FIG. 1 illustrates a portion 100 of a microchip, for the purposes of improved contextual understanding. In particular, the illustrated portion 100 comprises a voltage isolation system 110 and a voltage monitoring system 120.

One goal, known as isolation of power domains, of the voltage isolation system 110 is to ensure that no unexpected current path or power flow is formed or enabled during power up or during invalid supply voltage conditions. Such a current path or power flow may undesirably create erroneous signals, e.g., to or from the electronic circuit, which can result in unexpected behavior of the electronic circuit. In some applications, such as in the automotive industry, unexpected behavior could result in catastrophic error and/or damage

The voltage isolation system 110 of the microchip comprises a voltage isolation circuit 111 configured to control a power flow between a voltage line VL and an electronic circuit 190 responsive to a control signal SC.

The voltage line VL may, for instance, carry a circuit control signal for controlling an operation or function of the electronic circuit 190. It may be desirable to prevent the circuit control signal from controlling an operation of the electronic circuit until, for instance, the power supply/supplies in the microchip have settled or reached one or more predetermined levels. This reduces a risk of unexpected behavior of the electronic circuit 190.

The voltage isolation system 110 may, for instance, be formed from one or more level shifters having an enable/disable function. More particular, the level shifter(s) may be connected between the voltage line VL and the electronic circuit 190 and be configured to switchable (responsive to the control signal) between an enable state (in which current is permitted to flow between the voltage line VL and the electronic circuit) and a disable state (in which no or negligible current is permitted to flow between the voltage line VL and the electronic circuit).

The voltage isolation system 110 further comprises a reset control system 112 configured to generate the control signal SC for the voltage isolation circuit 111. In this way, the reset control system 112 controls the power flow between the voltage line VL and the electronic circuit 190 using the voltage isolation circuit 111 via the control signal SC.

More particularly, the reset control system 112 is configured to, after a startup of the microchip, initially control the voltage isolation circuit 111 to prevent power flow from the voltage line VL to the electronic circuit 190. The reset control system 112 is also configured to permit the voltage isolation circuit to allow power flow from the voltage line VL to the electronic circuit (e.g., release the level shifter(s)) only when the voltage on a supply line VS1 (e.g., for the electronic circuit 190) meets one or more predetermined conditions (e.g., is stable and/or breaches a predetermined voltage level). Thus, the reset control system 112 may monitor the voltage at the supply line, and generate the control signal responsive to the monitored voltage.

A supply line provides a supply voltage for powering the electronic circuit and/or one or more other elements of a system (e.g., microchip) comprising or containing the electronic circuit 190.

The reset control system 112 may require one or more additional conditions to be met before permitting the voltage isolation circuit to allow power flow from the voltage line VL to the electronic circuit 190. For instance, the reset control system 112 may also monitor a voltage on each of one or more further supply lines, such as a second supply line VS2. In such cases, the reset control system may permit the voltage isolation circuit to allow power flow from the voltage line to the electronic circuit (e.g., release the level shifter(s)) responsive to the voltage on each supply line VS1, VS2 meeting a respective set of one or more predetermined conditions (e.g., each voltage stable and/or breaches a predetermined voltage level for the supply line).

The reset control system 112 of the existing voltage isolation system 110 performs an analogue-based monitoring of the voltage on the supply line VL (and, if relevant, each further supply line VS2). In particular, the reset control system 112 comprises respective analogue comparators 113A, 113B and so on to compare the voltage on each supply line to a respective reference voltage VREF. The respective reference voltage(s) are produced by a bandgap voltage reference circuit BG or similar circuit of the reset control system 112. In some instances, the bandgap voltage reference circuit BG may be a power on reset generator. The reset control system 112 also comprises control logic 114 for generating the control signal when the voltage on each supply line breaches a predetermined threshold.

Separate from the voltage isolation system 110, the portion 100 of the microchip also comprises a voltage monitoring system 120. The voltage monitoring system 120 is configured to generate, for each supply line V21, VS2, a digital representation of the voltage on said supply line. Thus, each voltage monitoring system 120 may measure the voltage on the respective supply line(s) and produce a digital representation of this measure.

The digital representations of the voltage(s) of the supply line(s) produced by the voltage monitoring system 120 may, for instance, be used by a power management system (not illustrated in FIG. 1) to control the voltage on the supply line(s), e.g., to perform closed-loop feedback control of the voltage on the supply line(s).

With increasing numbers of supply lines in the microchip, the identification and selection of suitable reference voltages for all the supply lines becomes increasingly complex due to the need to account for tolerances in different components of the microchip. Moreover, there is a significant reliance upon (variably accurate due to manufacturing tolerances) analogue components for accurate control of the voltage isolation system.

The isolation and monitoring system may face additional complexity in implementations of the voltage isolation system that need to make use of CMOS devices (common in the art) that are unable to support supply voltages higher than those specified for the supply line. For example, there may be a need to provide isolation between a voltage line designed to carry a 3.3V and an electronic circuit using CMOS technology that only offers 1.8V-robust gates.

In such configurations, the voltage carried by the supply line may therefore function as a “high voltage”, which would therefore benefit from appropriate protection for circuit components. For the existing system, this protection needs to be implemented separately for the voltage isolation system and the voltage monitoring system.

Although high voltage protection can be achieved through stacking transistors (e.g., in a cascode), the stacked transistors may need to be properly biased to prevent overvoltage. This is achieved through use of a resistive divider that generates gate voltages for the cascode transistors. However, use of a resistive divider may require a static current on the supply line and a significant area for a high-impedance resistive divider-which are common. Moreover, this use of high-impedance resistive dividers limits the routing distance of bias lines for the cascode transistors (or face power consumption penalties). This may necessitate multiple instances of bias generators, further increasing area usage.

The present disclosure proposes a new approach for controlling current flow between the voltage line VL and the electronic circuit 190. In particular, the proposed approach proposes to effectively merge the voltage monitoring system and voltage isolation system into a single building block. More particularly, the reset control system is modified to instead generate the control signal responsive to the digital representation of the voltage(s) on the supply line(s) produced by the voltage monitoring system 120. Thus, generation of the control signal is performed responsive to processing of the monitored voltage(s) in the digital domain, rather than an analogue domain processing of the voltage(s) on the supply line(s).

The proposed approach thereby provides a voltage isolation circuit that is able to perform these two functions within a single integrated system, thereby reducing complexity, required chip area, and power consumption of the microchip. Existing solutions, as previously exemplified, relied on separate systems for voltage monitoring and power domain isolation, leading to increased chip area and power usage. This approach also reduces, if required, the amount of circuitry required to provide high voltage protection.

The proposed system also overcomes many of the disadvantages of the known analogue-based approach outlined above by pivoting to a digital-based approach.

FIG. 2 illustrates an example voltage isolation system 200 for use in a microchip. The voltage isolation system 200 is designed for controlling, in the microchip, a power flow from a voltage line VL to an electronic circuit 290. The voltage isolation system includes a voltage isolation circuit 210, a voltage monitoring system 220, and a reset control system 230.

The voltage isolation circuit 210 is configured to control power flow between the voltage line VL and the electronic circuit 290 in response to a control signal SC. This control may be performed by enabling or disabling current flow between the voltage line and the electronic circuit 290, which current flow is illustrated in FIG. 2 using a dashed line.

For instance, the voltage isolation circuit 210 may comprise one or more levelshifters for performing a level shifting operation between the voltage line VL and the electronic circuit 290. Each levelshifter may have an enable/disable functionality, as previously described.

The voltage monitoring system 220 is configured to generate a digital representation of the voltage at a supply line VS1 (e.g., for the electronic circuit 290). This digital representation thereby provides a measure of the voltage level on the supply line VS1 in a format suitable for digital processing. More particularly, the voltage monitoring system 220 comprises an analogue-to-digital converter 221 configured to generate the digital representation of the voltage at the supply line VS1. As a simple example, the voltage monitoring system 220 may comprise an analog-to-digital converter (ADC) that receives the voltage from the supply line VS1 as an input (e.g. via a sensing line) and produces the digital representation of the received voltage as an output.

The reset control system 230 receives and monitors the digital representation of the voltage at the supply line VS1 from the voltage monitoring system 220, e.g., over a digital communication line or the like. The reset control system 230 is configured to provide the control signal to the voltage isolation circuit 210, and thereby controls the operation of the voltage isolation circuit 210. In this way, the reset control system make control decisions based on digitized voltage information rather than analog comparisons.

In response to a startup of the microchip (e.g., resulting in a startup of the reset control system 230), the reset control system 230 initially controls the voltage isolation circuit 210, using the control signal, to prevent power flow from the voltage line VL to the electronic circuit 290. This helps avoid or significantly reduce a risk of issues or errors during the startup process.

After startup, the reset control system 230 is configured to permit the voltage isolation circuit 210 to allow power flow from the voltage line VL to the electronic circuit 290 only when one or more predetermined criteria are met. More specifically, the reset control system 230 is configured to, responsive to each of one or more first predetermined criteria being met after the startup of the microchip, permit the voltage isolation circuit to allow power flow from the voltage line VL to the electronic circuit 290.

The one or more first predetermined criteria includes at least a criterion that the digital representation of the voltage at the supply line VS1 meets (each of) one or more second predetermined criteria. As later exemplified, these second predetermined criteria may relate to voltage stability, voltage magnitude/level and/or other characteristics derivable from the digital representation of the voltage.

For instance, the second predetermined criterion may include at least a criterion that the digital representation of the voltage at the supply line indicates that the voltage at the supply line has settled.

By way of example only, a voltage at the supply line may be considered to have settled when the digital representation of the voltage indicates that that, for a predetermined period of time, the voltage at the supply line has not substantially changed, i.e., remains within a tolerance range. In this way, the reset control system is able to ensure that the voltage at the supply line VS1 has stabilized before allowing power flow to the electronic circuit 290 from the voltage line VL. This helps reduce a risk any potential issue from supplying an unstable voltage to sensitive components, e.g., unintentional triggering of one or more functions of the electronic circuit 290.

In some examples, the predetermined period of time may be greater than 5 us but less than 100 us, e.g., 10 us or 25 us. The predetermined period of time may be selected based on the specific characteristics of the supply line, the voltage line and/or the microchip, such as the expected settling time of the supply line at start up.

In some examples, the voltage at the supply line VS1 may be determined to have not substantially changed responsive to a difference between the maximum and minimum voltage (within the predetermined period of time) not exceeding a predetermined percentage of said maximum or minimum voltage. The predetermined percentage may, for instance, have a value of 10%, 5%, 2% or any other suitable value.

As another example, the voltage at the supply line VS1 may be considered to have settled when the digital representation of the voltage at the supply line VS1 indicates that the rate of change of the voltage at the supply VS1 line is below a predetermined threshold. This criterion helps ensure that the voltage is relatively stable. For instance, the reset control system may monitor the rate of change of the voltage over a specified time window and control the control signal to only permit power flow (from the voltage line VL to the electronic circuit 290) when this rate falls below a defined threshold, e.g., 1% change per microsecond.

In some examples, the second predetermined criteria may include at least a criterion that the digital representation of the voltage at the supply line VS1 indicates that the voltage at the supply line exceeds a predetermined voltage. The predetermined voltage may be a minimum desired voltage level for the supply line, which can be defined in advance (e.g., representing an expected magnitude of the voltage level for the supply line). In this way, the voltage isolation system is able to prevent flow from the voltage line to the electronic circuit 290 until the supply voltage has breached a minimum threshold.

In yet other examples, the second predetermined criteria may include at least a criterion that the digital representation of the voltage at the supply line indicates that the voltage at the supply line does not exceed a second predetermined voltage. The second predetermined voltage may be a maximum desired voltage level for the supply line, which can be defined in advance (e.g., representing an allowable maximum magnitude of the voltage level for the supply line). In this way, the voltage isolation system is able to prevent power flow to the electronic circuit 290 from the voltage line if the voltage at the supply line exceeds a safe operating range. This helps protect the electronic circuit 290 from potential damage due to overvoltage conditions and/or reduce a risk of false signals being interpreted by the electronic circuit 290.

A wide variety of other suitable examples of second predetermined criteria will be apparent to the skilled person.

Another example of a suitable first predetermined criteria is a criterion that a voltage of one or more further supply lines VS2 each meet one or more further predetermined criteria. These further predetermined criteria may effectively mirror the second predetermined criteria applied to the (primary) supply line VS1.

Thus, the reset control system may receive and monitor each a digital representation of a voltage at each of one or more further supply lines, such as a second supply line VS2, in a manner similar to that described for the supply line VS1.

In some examples, the voltage monitoring system 220 may be configured to generate the respective digital representation of a voltage at each of the one or more further supply lines, such as the second supply line VS2.

In some examples, the reset control system 230 may receive a respective digital representation(s) of a voltage at each of the one or more further supply lines over a digital input line DI1, e.g., from an element or component external to the voltage isolation system 200. By way of example, the digital input line DI1 may be connected to one or more digital output lines of one or more other voltage isolation systems.

Although only a single further supply line VS2 and a single digital input line DI1 is illustrated in FIG. 2, the skilled person will appreciate that, in practice, the microchip may comprise a plurality of further supply lines, e.g., a supply line for each power domain in the microchip, and/or a plurality of further digital input lines.

Accordingly, the reset control system 230 may be configured to permit the voltage isolation circuit to allow power flow from the voltage line VL to the electronic circuit 290 only when the digital representations of the voltages at both the primary supply line VS1 and the one or more further supply lines VS2 meet their respective predetermined criteria.

Thus, the one or more first criteria may include a criterion that the voltage at the supply line meets the one or more second predetermined criteria and a criterion that the voltage at each of the one or more further supply lines meet their respective predetermined criteria.

As previously mentioned, the further predetermined criteria for each further supply line may include similar conditions to those described for the second predetermined criteria.

For instance, the further predetermined criteria may include a criterion that the digital representation of the voltage at the further supply line indicates that the voltage of the further supply line has settled, using similar settling criteria as described for the supply line.

As another example, the further predetermined criteria may include a criterion that the respective digital representation of the voltage at the respective further supply line indicates that said voltage exceeds a predetermined minimum voltage level, e.g., specific to that supply line.

As yet another example, the further predetermined criteria may include a criterion that the respective digital representation of the voltage at the respective further supply line indicates that the voltage does not exceed a predetermined maximum voltage level, e.g., specific to that supply line.

A wide variety of other suitable examples for the further predetermined criteria will be readily apparent to the skilled person.

This approach effectively configures the reset control system to ensure that relevant power supplies in the system have reached stable and/or appropriate levels before allowing power flow from the voltage line VL to the electronic circuit 290. This approach aims to prevent issues that could arise from inconsistent or inappropriate voltage levels across different power domains within the microchip.

In some above-described approaches, such as in some examples of the second predetermined criteria, the voltage monitoring system 220 monitors the digital representation of the voltage at the supply line from the voltage monitoring system over a predetermined period of time. As such, there may be a desire to provide a clock source for accurately tracking the predetermined period of time

In some examples, the voltage isolation circuit comprises a dedicated clock source 235 configured to generate a clock signal for a clock line CLK connected to the reset control system 230. This clock source may be a crystal oscillator, a ceramic resonator, or any other suitable example of a clock source.

In other examples, the voltage isolation circuit comprises a clock line CLK connected to the reset control system 230 and for connection to an external clock source, that carries an (external) clock signal. This approach reduces area consumption, overall power consumption and facilitates microchip-wide timing coordination.

The clock signal, whether generated internally or received externally, may be used by the reset control system to sample the digital representation of the voltage at regular intervals. This sampling process allow the reset control system to accurately measure time-dependent criteria, such as the elapse of the predetermined period of time and/or voltage rates of change.

In some examples, the voltage monitoring system may incorporate the clock signal into its analog-to-digital conversion process. For example, the analog-to-digital converter may use the clock signal to determine its sampling rate.

To ensure reliable operation, the voltage isolation system may include mechanisms to verify the presence and stability of the clock signal. This may involve a clock detection circuit (e.g., in the form of a counter or watchdog) that monitors the clock signal and alerts other components if the clock becomes unstable or stops.

In some examples, as illustrated by FIG. 2, the voltage isolation system further comprises a reference voltage generator 240 configured to generate a reference voltage. The voltage monitoring system is configured to generate the digital representation of the voltage at the supply line with respect to the reference voltage.

As a simple example, the voltage monitoring system may comprise an analog-to-digital converter (ADC) that receives the voltage from the supply line VS1 as an input (e.g. via a sensing line). The ADC uses the reference voltage (produced by the reference voltage generator) as a reference for conversion, allowing it to measure the voltage at the supply line VS1 relative to the reference. The output of the ADC may be a digital value representing the measured voltage, i.e., a digital representation of the voltage at the supply line VS1.

A reference voltage generator in the voltage isolation system functions to provide a stable reference point for measuring the voltage at the supply line VS1 and, if present, and further supply line VS2. This reference voltage thereby serves as a baseline against which the voltage at the supply line VS1 (or, if present, further supply line VS2) can be accurately compared and digitized.

The reference voltage generator 240 may be implemented using a bandgap reference, which provides improved stability across temperature variations.

In some examples, the reference voltage generator may be powered by the voltage at the supply line. This eliminates the need for a separate power supply for the reference voltage generator.

In some examples, the reference voltage generator may be extended by further comprising a power-on reset (POR) generator. This extension may enhance the reliability and functionality of the voltage isolation system, particularly during startup conditions or when power supplies are in an invalid state.

The POR generator may be configured to monitor the voltage at the supply line and generate a reset signal when this voltage falls below a predetermined threshold. In particular, during startup or when power supplies are invalid, the POR generator may hold the reference voltage generator in a reset state. This prevents the reference voltage generator from producing potentially erroneous or unstable reference voltages that could lead to incorrect voltage measurements or system malfunctions. Once the voltage at the supply line reaches a stable and sufficient level, the POR generator may release the reset signal, allowing the reference voltage generator to begin normal operation.

The existing voltage isolation system (FIG. 1) relies upon one or more threshold levels defined for analog comparators (usually bandgap based). The accuracy of this analog solution therefore defines the performance of the voltage isolation system. By changing to the proposed solution, the bandgap generator needs to only cover valid ADC operation. The real accuracy for voltage isolation is therefore derived from ADC output, significantly improving the accuracy of the voltage isolation.

In some examples, as illustrated in FIG. 2, the voltage isolation system further comprises a high voltage protection circuit 250 connected between the supply line VS1 and the voltage monitoring system 220. Although not illustrated in FIG. 2, the voltage isolation system may (further) comprise one or more further high voltage protection circuits connected between the supply line VS1 and one or more respective other components of the voltage isolation system (such as between the supply line VS1 and the voltage isolation circuit 210 (e.g., the level shifter(s)) or the supply line VS1 and the reference voltage generator 240.

Examples of suitable high voltage protection circuits are known in the art, such as those that employ a cascode of (stacked) transistors to distribute voltage stress and an appropriately configured biasing arrangement (e.g., a voltage divider).

The proposed approach that effectively integrates voltage isolation and voltage monitoring functionality into a single system advantageously reduces the number of high voltage protection circuits needed by the overall microchip, as multiple voltage protection circuits (e.g., one for each system) are effectively merged into a single block, saving area and static current on the supply line VS1.

In some examples, the voltage monitoring system 100 comprises a digital output line DO1 configured to provide a digital signal derived from the digital representation of the voltage to an element external to the voltage isolation system.

In some examples, the digital signal on the digital output line DO1 carries the digital representation of the voltage on the supply line VS1. In this way, the digital representation of the voltage on the supply line VS1 may be provided to an element external to the voltage isolation system.

In some examples, the voltage isolation system 200 may include a digital filter system 260. The digital filter system is configured to receive the digital representation of the voltage (on the supply line VS1) from the voltage monitoring system, process this digital representation using one or more digital filters, and provide a filtered digital representation of the voltage as the digital signal on the digital output line. In this way, a filtered version of the digital representation of the voltage on the supply line VS1 may be provided to an element external to the voltage isolation system.

Various types of digital filters may be employed in the digital filter system. These may include, but are not limited to, low-pass filters, high-pass filters, band-pass filters, or more complex filter designs such as Kalman filters. The choice of filter type and parameters will depend upon the specific use-case scenario.

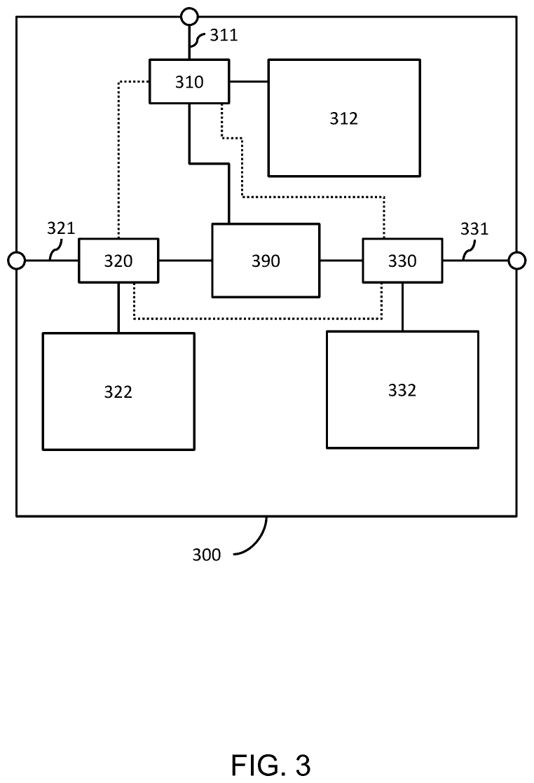

FIG. 3 schematically illustrates a microchip 300 that employs one or more proposed voltage isolation systems, e.g., a plurality of voltage isolation systems.

In particular, the microchip 300 comprises a plurality of voltage isolations systems 310, 320, 330. Each voltage isolation system 310, 320, 330 is configured to control a power flow from a respective supply line 311, 321, 331 to a respective electronic circuit 312, 322, 332.

Each supply line may be designed to carry a different voltage, e.g., a different voltage level. As such, each voltage isolation system 310, 320, 330 and/or each electronic circuit 312, 322, 332, may be configured to function or operate in a different power domain.

Each voltage isolation system is embodied as previously described, e.g., with reference to FIG. 2. In particular each voltage isolation system is configured to provide, at a respective digital output line DO1, DO2, DO3, a digital signal derived from the digital representation of the voltage at the respective supply line.

The microchip 300 further comprises a power management system 390 connected to the digital output line of each voltage isolation system. The power management signal therefore effectively receives a (e.g., filtered) digital representation of the voltage on each supply line 311, 321, 331.

The power management system 390 may be configured to, for each voltage isolation system, control the voltage on the respective supply line of said voltage isolation system responsive to the digital signal provided by the voltage isolation system. In particular, the microchip may comprise one or more voltage supplies and/or converters that generate the voltage(s) on each supply line 311, 321, 331. The power management system 390 may control the operation of each voltage supply and/or converter to control the voltage produced on each voltage supply. Example voltage supplies and/or converters are well known in the art, such as those that convert a mains power supply into a desired voltage.

The proposed approach effectively provides a distributed voltage monitoring scheme for the power management system 390, which avoids a need to directly route sensing lines from each supply line to the power management system. Rather, a digital representation of the voltage at each supply line can be produced by a respective voltage isolation system in close proximity to the supply line. This significantly reduces power consumption, electromagnetic interference and/or signal noise in the microchip.

It has previously been explained how a reset control system may be configured to make use of a respective digital representation of a voltage at each of one or more further supply lines.

In some variants, the voltage isolation system is configured to receive a digital representation of a voltage at each of the one or more further supply lines from one or more other voltage isolation systems and/or the power management system 390. The reset control system of the voltage isolation system may process the digital representation of each of these voltages using any previously described approach. As previously exemplified, the reset control system may use the received digital representations of voltages at the supply line and, optionally, one or more other supply lines as part of its criteria for allowing power flow. This approach ensures that multiple supply lines meet certain conditions before any single system allows power flow to its associated electronic circuit.

Thus, in some examples, each voltage isolation system may be configured to comprise only a single voltage monitoring system for a single supply line. In this way, each voltage isolation system is responsible for monitoring and controlling the power flow from a single supply line to its associated electronic circuit.

Moreover, the voltage isolation systems may be interconnected to share information about the voltages they are monitoring. Specifically, each voltage isolation system may be configured to receive, from each of one or more other voltage isolation systems, the digital representation of the voltage monitored by said voltage isolation system

This digital communication between the voltage isolation systems may be implemented through a communication network or bus that allows the voltage isolation systems to exchange digital information.

In some examples, the digital communication is coordinated or routed by another system of the microchip, such as the power management system 390 (which receives information on the voltage at each supply line-thereby providing a more efficient system for routing information). In this way, each voltage isolation system may have a digital output line that provides its monitored voltage information, and one or more input lines to receive voltage information from other systems and/or the power management system.

The present disclosure also proposes an improved approach to performing voltage monitoring. In particular, the present disclosure proposes an approach in which a master voltage monitor determines an error in a voltage reference generated by a first voltage reference generator, which is of a same type as a voltage reference generator of each of one or more voltage isolation systems. This determined error is used to correct an error in a voltage monitored by the voltage monitoring system of the voltage isolation system.

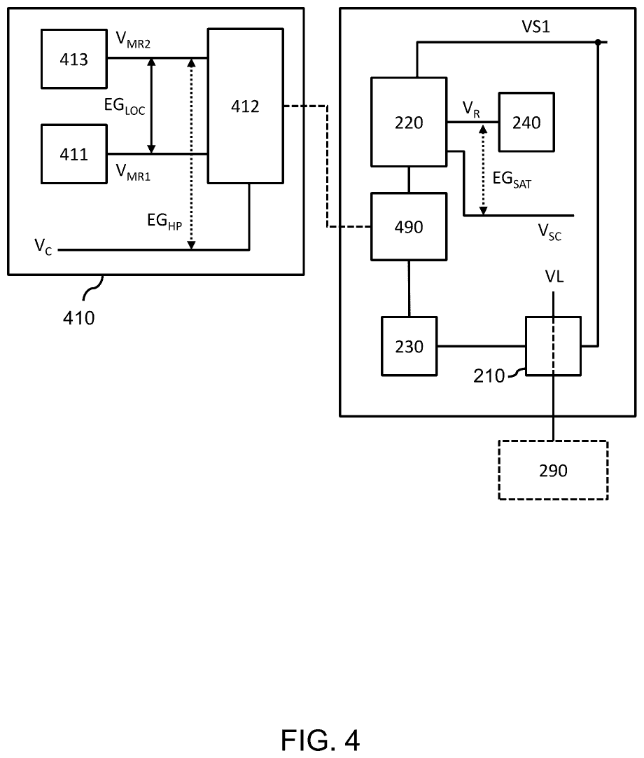

FIG. 4 illustrates a portion 400 of an example microchip, which includes a variant to the voltage isolation system.

The illustrated portion 400 comprises at least one voltage isolation system 200 as previously described, here a single voltage isolation system. Optional components of the voltage isolation system(s) 200 are not illustrated for illustrative clarity, but may be included in some variants.

Thus, the voltage isolation system 200 comprises a voltage isolation circuit 210, a voltage monitoring system 220 and a reset control system 230. For the purposes of this approach, the voltage isolation system 200 further comprises a reference voltage generator 240 configured to generate a reference voltage VR. The voltage monitoring system 220 is configured to generate a digital representation of the voltage at a supply line VS1 with respect to the reference voltage VR.

For the sake of illustrative clarify, only a single voltage isolation system 200 is illustrated although, in practice, the microchip may comprise a plurality of voltage isolation systems, e.g., a single voltage isolation system, two voltage isolation systems, three voltage isolation systems, four voltage isolation systems or more than four voltage isolation systems. In particular, the voltage monitoring system may comprise a voltage isolation system for each power domain of the microchip.

The microchip 400 also comprises a master voltage monitor 410, which comprises a first master reference voltage generator 411 that generates a first master reference voltage V_{MR1}. The first master voltage generator 411 also comprises an error determination system 412.

The error determination system 412 is configured to determine at least one digital error. In this context, a digital error is a digital representation responsive to a measure of error of the first master reference voltage. Suitable examples of digital errors that may be determined by the error determination system are provided later in this disclosure.

The reference voltage generator 240 (of the/each voltage isolation system 200) is of the same type as the first master reference voltage generator (i.e., is of the first type) to ensure similar error characteristics.

In this context, the “same type” refers to the reference voltage generator and the first master reference voltage generator being of the same design or configuration. This means they are constructed using similar circuit topologies, components, and principles, which results in comparable performance characteristics, especially in terms of their response to environmental factors like temperature changes. Similarly, different types of reference voltage generator (e.g., the first and second type-referred to later in this disclosure) have different designs or configurations, meaning they are constructed using different circuit topologies, components, and/or principles.

The/each voltage isolation system is thermally coupled to the master voltage monitor. This thermal coupling may be achieved by using a shared heat sink or other thermal management system. In this way, as the first master reference voltage generator 411 of the master voltage monitor 410 and the reference voltage generator(s) 240 of the voltage isolation system(s) 200 are of the same type, an error in the first master reference voltage due to thermal effects will be similar to the error in each reference voltage due to thermal effects.

As previously noted, where there are a plurality of voltage isolation systems, each voltage isolation system may be designed or configured to monitor a voltage for a different power domain of the microchip. In this way, the supply line for different voltage isolation systems may be configured to carry a power signal for a different one of a plurality of power domains.

The/each voltage isolation system 200 is configured to also comprise an error correction system 490 configured to correct at least one error in the digital representation of the voltage at the supply line VS1 using the at least one digital error determined by the master voltage monitor. In particular, each voltage isolation system 200 may include its own error correction system 490 that is integrated with the voltage isolation system.

The error correction system receives the at least one digital error from the error determination system (of the master voltage monitor), e.g., over a communication bus 495. The error correction system then uses the received at least one digital error to correct the corresponding digital representation of the voltage at the supply line. Some example approaches for correcting this digital representation of the voltage at the supply line are provided later in this disclosure.

It will be apparent that the error correction system functions or operates in the digital domain, and may be embodied using one or more (micro) processors or similar. Thus, the error correction system may comprise one or more processors or processing systems for processing the digital representation of the voltage at the supply line to produce a corrected measured voltage.

In the illustrated example, the error correction system is illustrated as a separate component to the voltage monitoring system and/or the reset control system. In practice, these modules and/or systems may be integrated into a single processing system.

It has been recognized that a significant source of error in producing a digital representation of a (measured) voltage is an error in the reference voltage against which the measured voltage is defined. The present disclosure provides a number of techniques for addressing this issue to thereby improve the accuracy of generating a digital representation of a voltage at the supply line (i.e., performing a voltage measurement). In particular, the present disclosure recognizes a variety of types of errors in the reference voltage(s) used to produce each voltage measurement and proposes techniques for at least partially attenuating these errors.

A first type of error in a reference voltage results from the reference voltage VR being generated using a less accurate, reliable or robust reference voltage generator.

To at least partially overcome this issue, the master voltage monitor 410 may comprise a second reference voltage generator 413 of a second type, which is less sensitive to changes in temperature than the first type (e.g., more accurate or more robust than the first type). This second reference voltage generator 413 produces a second master reference voltage V_{MR2}. The error determination system 412 of the master voltage monitor 410 may then determine, as a first digital error EG_{LOC}, a digital representation of an error between the first master reference voltage V_{MR1} and the second master reference voltage V_{MR2}.

The first type of reference voltage generator is less robust (e.g., more sensitive to thermal effects or temperature drift) and/or less accurate than the second type of reference voltage generator.

The first type of reference voltage generator may, for instance, be a bandgap voltage reference; and the second type of reference voltage generator may be a high precision bandgap voltage reference. Examples of high precision bandgap voltage references are well known in the art, such as those discussed by Zhou, Ze-Kun, et al. “A resistorless high-precision compensated CMOS bandgap voltage reference.” IEEE Transactions on Circuits and Systems I: Regular Papers 66.1 (2018): 428-437 and/or Xing, Xinpeng, Zhihua Wang, and Dongmei Li. “A low voltage high precision CMOS bandgap reference.” Norchip 2007. IEEE, 2007.

In some examples, the second type of reference voltage generator has a greater footprint, i.e., occupies a greater surface area, than the first type of reference voltage generator. A larger surface area occupation is usually required by more sophisticated (and accurate) reference voltage generators. Thus, the use of the first type of reference voltage generator in the voltage isolation system reduces a footprint of the voltage isolation system-whilst still allowing error(s) in the reference voltage generated by the reference voltage generator of the voltage isolation system to be corrected.

The first digital error is then passed to the error correction system, e.g., over the communication bus. The first digital error is then used by the error correction (e.g., by each error correction system) to correct the/each reference voltage.

As the first master reference voltage generator and the reference voltage generator(s) of each voltage isolation system are of a same type, it can similarly be assumed that any error in the first master reference voltage generator will also occur in the reference voltage generator, particularly any errors resulting from thermal effects or temperature drift.

The first digital error may be defined as a quotient of the second master reference voltage V_{MR2} and the first master reference voltage V_{MR1}, specifically V_{MR2}/V_{MR1}. In such an example, the error correction system may correct the first type of error in the digital representation of the voltage at the supply line by multiplying each measured voltage by this quotient (V_{MR2}/V_{MR1}). Other examples for defining an error and performing an appropriate correction will be apparent to the skilled person.

By using a more accurate second master reference voltage generator 413 in the master voltage monitor 410 and distributing the resulting error information, the proposed approach is able to compensate for inaccuracies in the less precise reference voltage generator 240 used in the/each voltage isolation system 200. This approach allows for the use of simpler, more cost-effective reference voltage generators in the voltage isolation systems while still maintaining high overall accuracy in voltage measurements.

A second type of error in a reference voltage results from a fixed ground error EG_{HP} in the second master reference voltage. This holds even when the second master reference voltage is produced using an accurate or reliable reference voltage generator (e.g., a high precision bandgap reference).

To at least partially overcome this second type of error, the error correction system may be configured to store a second digital error representing an error in the second master reference voltage. The error correction system may correspondingly be configured to use the stored second digital error to correct each measured voltage.

One approach to defining the second digital error is to provide a predetermined master calibration voltage V_{C} on a master calibration voltage line 415 and measuring this voltage with respect to the second master reference voltage V_{MR2}. This predetermined master calibration voltage may be known to the error determination system in advance (e.g., pre-programmed into the error determination system or defined by a user/operator).

The predetermined master calibration voltage may be provided, for instance, by an external high-precision voltage source connected to voltage monitoring system and/or the system-on-chip (e.g., during a calibration phase). This provides a highly accurate calibration voltage.

The master voltage monitor 410 may determine a digital representation of the voltage on the master calibration voltage line with respect to the second master reference voltage. The second digital error can then be defined responsive to a difference between the predetermined master calibration voltage and the digital representation of the measured voltage, which may then be passed to the error correction system 490 of the/each voltage isolation system 200. The second digital error represents the fixed ground error in the second master reference voltage, which may be due to offset voltages or other systematic errors in the voltage measurement system.

In some examples, the first master reference voltage generator 411 and/or the reference voltage generator 240 (of the/each voltage isolation system 200) are configured to generate their respective reference voltages using a chopping technique. This helps ensure that temperature drift and/or temperature inaccuracies of these reference voltage generators are the same (making the first digital error accurately representative of error due to temperature drift in each reference voltage generator—as well as the first master reference voltage generator).

The second digital error EG_{HP} may be defined as a ratio/quotient of the predetermined master calibration voltage V_{C} and the digital representation of the voltage on the master calibration voltage line VCML, specifically V_{C}/VCML. In such an example, the error correction system may correct the second type of error in each measured voltage by multiplying each measured voltage by this quotient (V_{C}/VCML). Other examples for defining an error and performing an appropriate correction will be apparent to the skilled person.

It will be appreciated that correcting the first type of error (EG_{LOC}) and the second type of error (EG_{HP}) also functions to correct the/any fixed/ground error in the first master reference voltage V_{MR1}.

In some examples, the master calibration voltage line may be the supply line for powering the master voltage monitor, e.g., for powering at least the error determination system.

A third type of error in a reference voltage results from a fixed/ground error EG_{SAT} in the reference voltage VR generated by the reference voltage generator 240 of the/each voltage isolation system 200.

To at least partially overcome this third type of error, the error correction system 490 may be configured to store, for the respective voltage isolation system 200, a third digital error EG_{SAT} representing a fixed/ground error in the reference voltage VR. The error correction system 490 may correspondingly be configured to use the stored third digital error EG_{SAT} to correct each measured voltage.

One approach to defining the third digital error is to provide, for each voltage isolation system 490, a predetermined calibration voltage V_{SC} on a calibration voltage line CVL for said voltage isolation system 200. The/each voltage isolation system, specifically the voltage monitoring system, may measure the voltage on its respective supply line with respect to its reference voltage. The/each predetermined calibration voltage may be known to the error correction system in advance (e.g., pre-programmed into the error correction system or defined by a user/operator).

The predetermined calibration voltage(s) may be provided, for instance, by an external high-precision voltage source connected to voltage monitoring system and/or the system-on-chip (e.g., during a calibration phase). This provides a highly accurate calibration voltage.

Each third digital error can then be defined responsive to, for each voltage isolation system, the difference between the predetermined calibration voltage and the digital representation of the measured voltage on the calibration voltage line. Each third digital error represents the fixed ground error in the corresponding reference voltage. The defined third digital error may then be stored by the voltage correction system 490 for future use.

For each voltage isolation system, the corresponding third digital error may be defined as a ratio/quotient of the predetermined calibration voltage V_{SC} and the digital representation of the voltage V_{CSL} on the calibration voltage line, specifically V_{SC}/V_{CSL}. In such an example, the error correction system may correct the third type of error in each measured voltage by multiplying each measured voltage by the corresponding quotient (V_{SC}/V_{CSL}). Other examples for defining an error and performing an appropriate correction will be apparent to the skilled person.

In some examples, for the/each voltage isolation system, the calibration voltage line CVL may be the power line for powering said voltage isolation system, e.g., the supply line VS1.

In some examples, when there is more than one voltage isolation system, the calibration voltage lines of all voltage isolation systems may be electrically connected together. In this way, the same predetermined calibration voltage may be shared by each voltage isolation system.

In examples where both a master calibration voltage and a calibration voltage for the/each voltage isolation system are provided, then the calibration voltage line of each voltage isolation system may be electrically connected to the master calibration voltage line of the master voltage monitor, such that each predetermined calibration voltage V_{SC} is the same as the predetermined master calibration voltage V_{C}.

The foregoing examples provide example approaches for determining three different digital errors (for the/each voltage isolation system), namely a first digital error EG_{LOC}, a second digital error EG_{HP} and a third digital error EG_{SAT}. The first and second digital errors are determined using the master voltage monitor, and are common to all voltage isolation systems. The third digital error is determined using each voltage isolation system separately, such that each third digital error EG_{SAT} is specific to a particular voltage isolation system.

Where each digital error is represented by a ratio, then the correction to the voltage monitored by the voltage monitoring system of the voltage isolation system can be performed by multiplying said voltage by each determined digital error (for the corresponding voltage isolation system).

Thus, a corrected voltage V_{SATC} may be calculated using the following equation:

$${V}_{SATC} = {V}_{SAT} \cdot {EG}_{LOC} \cdot {EG}_{HP} \cdot {EG}_{SAT} = {V}_{SAT} \cdot {EG}_{COM} \qquad ( 1 )$$

where VSAT is the voltage monitored by the voltage monitoring system of the voltage isolation system, EG_{LOC} is the first digital error, EG_{HP} is the second digital error, EG_{SAT} is the third digital error and EG_{COM} is the product of the first digital error, the second digital error and the third digital error.

In some examples, the master voltage monitor may be integrated into a voltage isolation system. Thus, the master voltage monitor may be further configured to monitor a voltage at a master voltage line and control a power flow between the master voltage line and further electronic circuitry. This effectively performs the functions of a voltage isolation system in addition to its role of producing at least one digital error. This dual functionality may be achieved by incorporating appropriate additional components and circuitry within the master voltage monitor.

For instance, the master voltage monitor may include a master voltage isolation circuit, a master voltage monitoring system and a master reset control system, which may function in a similar manner to the corresponding components of the voltage isolation system.

The master voltage monitor may further comprise a master error correction system to correct the measured voltage from the master voltage line using similar principles and techniques to those previously disclosed. This may include using the digital errors determined by the error determination system to correct any inaccuracies in the measured voltage from the master voltage line.

An error in the measured voltage from the master voltage line may be corrected differently depending on which master reference voltage is used for the measurement by the master voltage monitoring system. For instance, when the master voltage is measured with reference to the first master reference voltage (V_{MR1}), both the fixed ground error (EG_{HP}) and the local error (EG_{LOC}) need to be corrected. However, when the master voltage is measured with reference to the second master reference voltage (V_{MR2}), only the fixed ground error (EG_{HP}) needs to be corrected.

By incorporating this additional voltage monitoring capability, the master voltage monitor may provide voltage measurements for its own power domain, providing a more efficient microchip.

In addition to the above-described examples, the following examples are disclosed.

Example 1. A voltage isolation system for controlling, in a microchip, a power flow from a voltage line to an electronic circuit, the voltage isolation circuit comprising:
a voltage isolation circuit configured to control a power flow between the voltage line and the electronic circuit responsive to a control signal;
a voltage monitoring system configured to generate a digital representation of a voltage at a supply line for the electronic circuit; and
a reset control system configured to:
   provide the control signal to the voltage isolation circuit and:
   receive and monitor the digital representation of the voltage at the supply line from the voltage monitoring system,
wherein the reset control system is further configured to, responsive to a startup of the microchip:
   initially control, using the control signal, the voltage isolation circuit to prevent power flow from the voltage line to the electronic circuit; and
   responsive to each of one or more first predetermined criteria being met after the startup of the microchip, permit the voltage isolation circuit to allow power flow from the voltage line to the electronic circuit,
   wherein the one or more first predetermined criteria includes a criterion that the digital representation of the voltage at the supply line meets each of one or more second predetermined criteria after the startup of the microchip.

Example 2. The voltage isolation system of example 1, wherein the one or more second predetermined criteria includes a criterion that the digital representation of the voltage at the supply line indicates that the voltage at the supply line has settled.

Example 3. The voltage isolation system of example 1 or 2, wherein the one or more second predetermined criteria includes a criterion that the digital representation of the voltage at the supply line indicates that the voltage at the supply line exceeds a predetermined voltage.

Example 4. The voltage isolation system of any one of examples 1 to 3, further comprising a reference voltage generator configured to generate a reference voltage, wherein the voltage monitoring system is configured to generate the digital representation of the voltage at the supply line with respect to the reference voltage.

Example 5. The voltage isolation system of example 4, wherein the reference voltage generator is powered by the voltage at the supply line.

Example 6. The voltage isolation system of any one of examples 4 or 5, wherein the reference voltage generator is a bandgap reference.

Example 7. The voltage isolation system of any one of examples 1 to 6, wherein the voltage isolation circuit comprises one or more levelshifters for performing a level shifting operation between the voltage line and the electronic circuit.

Example 8. The voltage isolation system of any one of examples 1 to 7, further comprising a high voltage protection circuit connected between the supply line and the voltage monitoring system.

Example 9. The voltage isolation system of any one of examples 1 to 8, wherein the voltage monitoring system comprises a digital output line configured to provide a digital signal derived from the digital representation of the voltage to an element external to the voltage isolation system.

Example 10. The voltage isolation system of example 9, wherein the voltage monitoring system comprises a digital filter system configured to:
receive the digital representation of the voltage from the voltage monitoring system;
process the digital representation of the voltage using one or more digital filters to produce a filtered digital representation of the voltage; and
provide, as the digital signal, the filtered digital representation of the voltage on the digital output line.

Example 11. A microchip comprising:
one or more voltage isolations systems of any of examples 9 or 10;
for each voltage isolation system: a respective electronic circuit and a respective supply line; and
a power management system connected to the digital output line of each voltage isolation system and configured to, for each voltage isolation system, control the voltage on the respective supply line of said voltage isolation system responsive to the digital signal provided by the voltage isolation system.

Example 12. The microchip of example 11, wherein each voltage isolation system operates in a different voltage supply domain.

Example 13. The microchip of example 11 or 12, wherein:
each voltage isolation system is as exemplified in any one of examples 4 to 6; and
the microchip comprises a master voltage monitor communicatively coupled to each voltage isolation system over a communication bus, the master voltage monitor comprising:
a first master reference voltage generator configured to generate a first master reference voltage, wherein the first master reference voltage generator is of a first type; and
an error determination system configured to determine, as a digital error, a digital representation responsive to a measure of error of the first master reference voltage,
wherein for each voltage isolation system:
   the reference voltage generator is of the first type; and
   the voltage isolation system further comprises an error correction system communicatively connected to the error determination system of the master voltage monitor over the communication bus, wherein the error correction system is configured to correct an error in the digital representation of the voltage at the supply line using the digital error.

Example 14. The microchip of example 13, wherein the error determination system of the master voltage monitor comprises:
a second master reference voltage generator configured to generate a second master reference voltage, wherein the second master reference voltage generator is of a second type that is less sensitive to changes in temperature than the first type; and
a digitization system configured to determine, as the digital error, a digital representation of a difference between the first master reference voltage and the second master reference voltage.

Example 15. The microchip of example 14, wherein the error determination system comprises a master voltage measurement system configured to:
measure, as a first master measured voltage, a digital representation of a voltage at a first supply line with respect to the first master reference voltage; and
measure, as a second master measured voltage, a digital representation of the voltage at the first supply line with respect to the second master reference voltage; and wherein
the digitization system is configured to determine, as the digital error, a digital representation responsive to a difference between the first master measured voltage and the second master measured voltage.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the systems including its preferred embodiments as outlined in the present document may be used stand-alone or in combination with the other systems disclosed in this document. Furthermore, all aspects of the systems outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A voltage isolation system for controlling, in a microchip, a power flow from a voltage line to an electronic circuit, the voltage isolation system comprising:
a voltage isolation circuit configured to control a power flow between the voltage line and the electronic circuit responsive to a control signal;
a voltage monitoring system configured to generate a digital representation of a voltage at a supply line for the electronic circuit; and
a reset control system configured to:
provide the control signal to the voltage isolation circuit and:
receive and monitor the digital representation of the voltage at the supply line from the voltage monitoring system,
wherein the reset control system is further configured to, responsive to a startup of the microchip:
initially control, using the control signal, the voltage isolation circuit to prevent power flow from the voltage line to the electronic circuit; and
responsive to each of one or more first predetermined criteria being met after the startup of the microchip, permit the voltage isolation circuit to allow power flow from the voltage line to the electronic circuit,
wherein the one or more first predetermined criteria includes a criterion that the digital representation of the voltage at the supply line meets each of one or more second predetermined criteria after the startup of the microchip.

2. The voltage isolation system of claim 1, wherein the one or more second predetermined criteria includes a criterion that the digital representation of the voltage at the supply line indicates that the voltage at the supply line has settled.

3. The voltage isolation system of claim 1, wherein the one or more second predetermined criteria includes a criterion that the digital representation of the voltage at the supply line indicates that the voltage at the supply line exceeds a predetermined voltage.

4. The voltage isolation system of claim 1, further comprising a reference voltage generator configured to generate a reference voltage, wherein the voltage monitoring system is configured to generate the digital representation of the voltage at the supply line with respect to the reference voltage.

5. The voltage isolation system of claim 4, wherein the reference voltage generator is powered by the voltage at the supply line.

6. The voltage isolation system of claim 4, wherein the reference voltage generator is a bandgap reference.

7. The voltage isolation system of claim 1, wherein the voltage isolation circuit comprises one or more level shifters for performing a level shifting operation between the voltage line and the electronic circuit.

8. The voltage isolation system of claim 1, further comprising a high voltage protection circuit connected between the supply line and the voltage monitoring system.

9. The voltage isolation system of claim 1, wherein the voltage monitoring system comprises a digital output line configured to provide a digital signal derived from the digital representation of the voltage to an element external to the voltage isolation system.

10. The voltage isolation system of claim 9, wherein the voltage monitoring system comprises a digital filter system configured to:
receive the digital representation of the voltage from the voltage monitoring system;
process the digital representation of the voltage using one or more digital filters to produce a filtered digital representation of the voltage; and
provide, as the digital signal, the filtered digital representation of the voltage on the digital output line.

11. A microchip comprising:
one or more voltage isolation systems, each voltage isolation system comprising
a voltage isolation circuit configured to control a power flow between a voltage line and an electronic circuit responsive to a control signal;
a voltage monitoring system configured to generate a digital representation of a voltage at a supply line for the electronic circuit, comprising a digital output line configured to provide a digital signal derived from the digital representation of the voltage; and
a reset control system configured to:
provide the control signal to the voltage isolation circuit and:
receive and monitor the digital representation of the voltage at the supply line from the voltage monitoring system,
wherein the reset control system is further configured to, responsive to a startup of the microchip:
initially control, using the control signal, the voltage isolation circuit to prevent power flow from the voltage line to the electronic circuit; and
responsive to each of one or more first predetermined criteria being met after the startup of the microchip, permit the voltage isolation circuit to allow power flow from the voltage line to the electronic circuit,
wherein the one or more first predetermined criteria includes a criterion that the digital representation of the voltage at the supply line meets each of one or more second predetermined criteria after the startup of the microchip;
for each voltage isolation system, a respective electronic circuit and a respective supply line; and
a power management system connected to the digital output line of each voltage isolation system and configured to, for each voltage isolation system, control the voltage on the respective supply line of said voltage isolation system responsive to the digital signal provided by the voltage isolation system.

12. The microchip of claim 11, wherein each voltage isolation system operates in a different voltage supply domain.

13. The microchip of claim 11, wherein:
each voltage isolation system comprising a reference voltage generator configured to generate a reference voltage, wherein the voltage monitoring system is configured to generate the digital representation of the voltage at the supply line with respect to the reference voltage; and
the microchip comprises a master voltage monitor communicatively coupled to each voltage isolation system over a communication bus, the master voltage monitor comprising:
a first master reference voltage generator configured to generate a first master reference voltage, wherein the first master reference voltage generator is of a first type; and
an error determination system configured to determine, as a digital error, a digital representation responsive to a measure of error of the first master reference voltage,
wherein for each voltage isolation system:
the reference voltage generator is of the first type; and
the voltage isolation system further comprises an error correction system communicatively connected to the error determination system of the master voltage monitor over the communication bus, wherein the error correction system is configured to correct an error in the digital representation of the voltage at the supply line using the digital error.

14. The microchip of claim 13, wherein the error determination system of the master voltage monitor comprises:
a second master reference voltage generator configured to generate a second master reference voltage, wherein the second master reference voltage generator is of a second type that is less sensitive to changes in temperature than the first type; and
a digitization system configured to determine, as the digital error, a digital representation of a difference between the first master reference voltage and the second master reference voltage.

15. The microchip of claim 14, wherein the error determination system comprises a master voltage measurement system configured to:
measure, as a first master measured voltage, a digital representation of a voltage at a first supply line with respect to the first master reference voltage; and
measure, as a second master measured voltage, a digital representation of the voltage at the first supply line with respect to the second master reference voltage; and wherein
the digitization system is configured to determine, as the digital error, a digital representation responsive to a difference between the first master measured voltage and the second master measured voltage.

16. A voltage isolation system, comprising:
a voltage isolation circuit configured to control flow of power on a supply line to an electronic circuit responsive to a control signal; and
a reset control system configured to
receive, from a voltage monitoring system, a digital representation of voltage on the supply line; and
generate the control signal based on the digital representation of the voltage on the supply line.

17. The voltage isolation system of claim 16, wherein the reset control system is configured to
during an initial period after startup of the electronic circuit, generate a first control signal that controls the voltage isolation circuit to prevent the flow of power; and
after the initial period, generate a second control signal that controls the voltage isolation circuit to allow the flow of power in response to the digital representation of the voltage on the supply line meeting a criteria.

18. The voltage isolation system of claim 17, wherein the criteria comprises the digital representation of the voltage at the supply line indicating that the voltage at the supply line has settled.

19. The voltage isolation system of claim 17, wherein the criteria comprises the digital representation of the voltage at the supply line indicating that the voltage at the supply line exceeds a threshold voltage.

20. The voltage isolation system of claim 16, further comprising a filter disposed between the voltage monitoring system and the reset control system that filters the digital representation of voltage on the supply line.
